(19) United States
(12) Patent Application Publication
(10) Pub. No.: US 2024/0246258 A1
(43) Pub. Date: Jul. 25, 2024

(54) CERAMIC WAFER AND MANUFACTURING METHOD THEREOF

(71) Applicant: Hong Chuang Applied Technology Co., Ltd., Zhubei City (TW)

(72) Inventors: YAN-KAI ZENG, Zhubei City (TW); BAI-XUAN JIANG, Zhubei City (TW); RUI-FENG JIANG, Zhubei City (TW)

(21) Appl. No.: 18/341,423

(22) Filed: Jun. 26, 2023

(30) Foreign Application Priority Data
Jan. 19, 2023 (TW) 112102733

(51) Int. Cl. B28B 11/00; C04B 35/64

(52) U.S. Cl. CPC B28B 11/003; C04B 35/64; H01L 23/15

(57) ABSTRACT

A ceramic wafer includes an upper surface and a lower surface, and the ceramic wafer includes at least one curved surface. A manufacturing method of the ceramic wafer includes the steps of: performing a high-temperature sintering process on a ceramic green body to produce a ceramic material; and performing a processing process on the ceramic material to form the ceramic wafer, wherein the processing process is used to change the shape of the ceramic material and thereby form the ceramic wafer. The ceramic wafer and the manufacturing method thereof are advantageous in that by forming a warped or bowed ceramic wafer, it is made possible for the surface tension or surface internal stress resulting from forming a thick integrated circuit film on the ceramic wafer to pull the ceramic wafer into a relatively flat configuration suitable for subsequent manufacturing processes that require wafer flatness.

### BACKGROUND OF THE INVENTION

### 1. Technical Field

The present invention relates to a ceramic wafer and a manufacturing method thereof, but is not limited thereto.

### 2. Description of Related Art

Semiconductors are indispensable to the electronics industry, and wafer processing plays a crucial role in semiconductor device fabrication. Wafer processing includes operations in the upstream sector of the industry such as wafer fabrication, integrated circuit (IC) design, and photomask preparation, and also operations in the downstream sector of the industry such as IC encapsulation, testing, and packaging; the manufacture of lead frames, connectors, and other peripherals; and the manufacture of circuit boards. Wafer fabrication is one of the initial stages of semiconductor device fabrication and is the foundation of the semiconductor industry. Generally, semiconductor wafers are made by forming a single-crystal ingot through a series of steps including silica sand refinement, fractional distillation, purification, melting, and pulling; slicing the single-crystal ingot; and polishing the slices obtained.

Ceramics have high hardness, a high melting point, and chemical stability, and are used extensively in our daily lives, for example as floor tiles and as dishes and bowls for serving food. The recently developed “fine ceramics” are different from the traditional ceramics. Fine ceramics are products made from refined and high-purity inorganic materials whose composition and uniformity are controlled by a chemical or physical method, and they are shaped by dry pressing, slip casting, injection molding, or other processes before being sintered. Featuring resistance to acids and alkalis, high hardness, wear resistance, pressure resistance, heat resistance, a low dielectric constant, electrical insulation, high thermal conductivity, efficient heat dissipation, and high stability in a high-humidity environment, fine ceramics are suitable for use in packaged semiconductor wafers and can be employed in various fields such as electronic ceramics, structural ceramics, and biomedical ceramics.

### BRIEF SUMMARY OF THE INVENTION

Currently, the metal circuit films or semiconductor circuit films used on ceramic substrates are of great thicknesses, and the inventor of the present invention has found that such a thick film may result in surface tension or surface internal stress that warps or bows the underlying substrate, which is supposed to be flat. The warp or bow, if present, will be disadvantageous to subsequent manufacturing processes that require wafer flatness. The inventor has also found that by forming a warped or bowed substrate, it is made possible for the surface tension or surface internal stress caused by forming a thick IC film on the substrate to pull the substrate into a relatively flat configuration suitable for subsequent manufacturing processes that require wafer flatness.

The present invention provides a ceramic wafer that includes an upper surface and a lower surface, and the ceramic wafer includes at least one curved surface. Preferably, the ceramic wafer includes two curved surfaces.

In one or more embodiments, the ceramic wafer includes an oxide ceramic, a nitride ceramic, or a carbide ceramic.

In one or more embodiments, the ceramic wafer includes a bow ranging from +/−0.1 μm to 1000 μm.

In one or more embodiments, the ceramic wafer includes a warp greater than or equal to 0.1 μm.

The present invention also provides a manufacturing method of a ceramic wafer, and the manufacturing method includes the steps of: performing a high-temperature sintering process on a ceramic green body to produce a ceramic material; and performing a processing process on the ceramic material to form the ceramic wafer, wherein the processing process is used to change the shape of the ceramic material and thereby form the ceramic wafer.

In one or more embodiments, the processing process is a grinding, polishing, or machining process for imparting different surface roughnesses to an upper surface and a lower surface of the ceramic material respectively, or for imparting a plurality of surface roughnesses to the upper surface of the ceramic material, or for imparting a plurality of surface roughnesses to the lower surface of the ceramic material, in order to change the shape of the ceramic material.

In one or more embodiments, the processing process involves providing a pressing plate and a supporting plate on an upper surface and a lower surface of the ceramic material respectively in order to change the shape of the ceramic material.

In one or more embodiments, the processing process involves heating the ceramic material at different temperatures or at different temperature increasing and/or decreasing rates from around the ceramic material in order to change the shape of the ceramic material.

In one or more embodiments, the high-temperature sintering process is followed by a high-temperature annealing process for controlling the increase and/or decrease of the internal stress of the ceramic material in order to change the shape of the ceramic material.

The ceramic wafer and the manufacturing method thereof provided by the present invention are advantageous in that, by forming a warped or bowed ceramic wafer, the surface tension or surface internal stress resulting from forming a thick IC film on the ceramic wafer is allowed to pull the ceramic wafer into a relatively flat configuration suitable for subsequent manufacturing processes that require wafer flatness.

### BRIEF DESCRIPTION OF THE SEVERAL VIEWS OF THE DRAWINGS

The foregoing and other objectives, features, advantages, and embodiments of the present invention can be better understood by referring to the following detailed description in conjunction with the accompanying drawings, in which:

FIG. 1 shows the schematical view of the ceramic wafers according to different embodiments of the present invention;

FIG. 2 to FIG. 6 are flowcharts of the manufacturing methods of the ceramic wafer according to different embodiments of the present invention; and

FIG. 7 shows the schematical view of the manufacturing method of the ceramic wafer according to an embodiment of the invention.

As is conventional, the features and elements in the drawings are not drawn to scale but are drawn to best show specific features and elements that are relevant to the present invention. In addition, the same reference numeral or similar reference numerals are used in the drawings to indicate similar elements or parts.

### DETAILED DESCRIPTION OF THE INVENTION

An explanatory description of certain aspects and embodiments of the present invention is given below to provide a more detailed and thorough account of the invention. The description, however, is not restrictive of the ways in which the invention can be implemented or used. Unless otherwise specified in the context, the articles “a” and “the” used in this specification and the appended claims include plural referents. Besides, unless otherwise specified, the expression “provided on something” used in this specification and the appended claims may refer to being attached to something directly or indirectly or being in contact with the surface of something in other ways, wherein the “surface” should be defined according to the context and according to common knowledge in the field to which the invention pertains.

All the numerical ranges and parameters used to define the present invention are approximate values. Efforts have been made, however, to present numerical values associated with each embodiment as precisely as possible. It should nevertheless be understood that, basically, each numerical value inevitably has a standard deviation attributable to the individual test method used. Herein, the term “about” when used in conjunction with a numerical value or range generally indicates that the actual value or range is within ±10%, 5%, 1%, or 0.5% of the value or range specified. Or, the term “about” may indicate that the actual value falls within an acceptable standard deviation of the average value specified. Which of the foregoing meanings of the term “about” applies in each instance of use of the term can be determined by a person of ordinary skill in the art. Therefore, unless stated to the contrary, all the numerical values disclosed in this specification and the appended claims are approximate values and may vary as needed. The numerical parameters disclosed herein should be construed at least as values having the significant figures specified and obtained by a common rounding method.

Besides, the blocks shown in the drawings may represent functions, steps, or hardware, and do not necessarily correspond to physically or logically independent entities. Moreover, each block in the drawings may be implemented by software, hardware, or a combination of software and hardware.

One aspect of the present invention relates to a ceramic wafer that includes an upper surface and a lower surface. Furthermore, the ceramic wafer includes at least one curved surface. The expression “the ceramic wafer includes at least one curved surface” means that at least one side of the ceramic wafer has a curvature. For example, at least one side of the ceramic wafer has a curvature greater than 0. According to a preferred embodiment of the invention, the ceramic wafer includes two curved surfaces; in other words, the ceramic wafer has two sides whose curvatures are greater than 0. More preferably, the two curved surfaces are defined by two opposite sides of the ceramic wafer respectively (i.e., one defined by the front side, and the other by the backside) so as to jointly contribute to the subsequent formation of surface tension or surface internal stress that helps pull the ceramic wafer into a relatively flat configuration.

According to some embodiments of the present invention, the ceramic wafer includes an oxide ceramic, a nitride ceramic, a carbide ceramic, or a combination of the above. For example, the ceramic wafer may include an oxide ceramic, a nitride ceramic, a carbide ceramic, a combination of an oxide ceramic and a nitride ceramic, a combination of an oxide ceramic and a carbide ceramic, a combination of a nitride ceramic and a carbide ceramic, or a combination of an oxide ceramic, a nitride ceramic, and a carbide ceramic.

According to some embodiments of the present invention, the ceramic wafer includes a bow ranging from +/−0.1 μm to 1000 μm, e.g., from +/−0.1 μm to 1000 μm, from +/−0.1 μm to 800 μm, from +/−0.1 μm to 600 μm, from +/−0.1 μm to 400 μm, from +/−0.1 μm to 200 μm, from +/−200 μm to 1000 μm, from +/−200 μm to 800 μm, from +/−200 μm to 600 μm, from +/−200 μm to 400 μm, from +/−400 μm to 1000 μm, from +/−400 μm to 800 μm, from +/−400 μm to 600 μm, from +/−600 μm to 1000 μm, from +/−600 μm to 800 μm, or from +/−800 μm to 1000 μm. Preferably, the bow ranges from +/−15 μm to 1000 μm. As used herein, the term “bow” is a shape parameter used to describe the curvature of an entire wafer, and is numerically defined as the deviation of the center point of the median surface of a wafer under test from a reference plane. Methods for determining the bow are well known to a person skilled in the art, and the invention has no limitation on which method is used.

In a preferred embodiment, the ceramic wafer includes a warp that is greater than or equal to 0.1 μm, e.g., greater than or equal to 0.1 μm, greater than or equal to 1 μm, greater than or equal to 5 μm, greater than or equal to 10 μm, greater than or equal to 15 μm, greater than or equal to 20 μm, greater than or equal to 25 μm, greater than or equal to 30 μm, greater than or equal to 35 μm, greater than or equal to 40 μm, greater than or equal to 45 μm, or greater than or equal to 50 μm. Preferably, the warp is greater than or equal to 30 μm. As used herein, the term “warp” is also a shape parameter used to describe the curvature of an entire wafer, and is numerically defined as the distance between the two points on the median surface of a wafer under test that are the farthest away from each other in the height direction. Methods for determining the warp are well known to a person skilled in the art, and the invention has no limitation on which method is used.

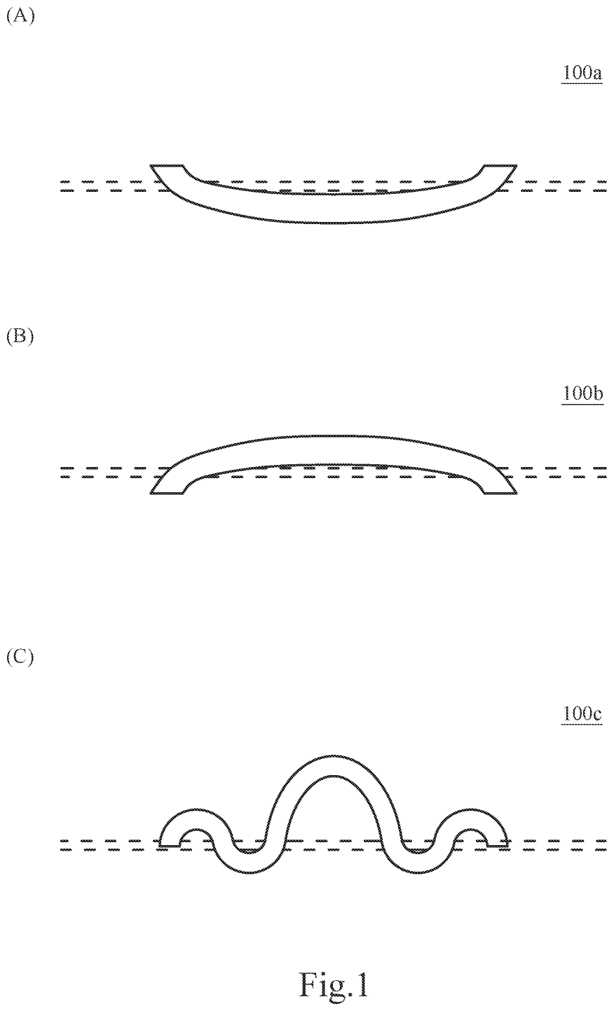

Please refer to FIG. 1. FIG. 1(A) shows the ceramic wafer 100a according to an embodiment of the present invention, wherein the ceramic wafer 100a is concave upward (i.e., bows or warps downward) and has one curved surface. FIG. 1(B) shows the ceramic wafer 100b according to another embodiment of the invention, wherein the ceramic wafer 100b is concave downward (i.e., bows or warps upward) and has one curved surface. FIG. 1(C) shows the ceramic wafer 100c according to still another embodiment of the invention, wherein the ceramic wafer 100c has multiple curved surfaces. As shown in FIG. 1(A) to (C), the ceramic wafer of the invention has at least one curved surface or preferably two curved surfaces, wherein the two curved surfaces are defined by two opposite sides of the ceramic wafer respectively (i.e., one defined by the front side, and the other by the backside). Preferably, the two curved surfaces are curved in the same direction. More preferably, each of the two curved surfaces has multiple curvatures (e.g., both curved surfaces have a wavy shape as in the case of the ceramic wafer 100c).

Another aspect of the present invention relates to a manufacturing method of a ceramic wafer. The manufacturing method includes the steps of: performing a high-temperature sintering process on a ceramic green body to produce a ceramic material; and performing a processing process on the ceramic material to form the ceramic wafer, wherein the processing process is used to change the shape of the ceramic material and thereby form the ceramic wafer.

The “ceramic green body” in the present invention includes a metal compound. The metal compound is selected from the group consisting of a metal oxide, a metal nitride, and a metal carbide, and the metal in the metal compound is selected from the group consisting of aluminum, silicon, titanium, zirconium, lead, vanadium, niobium, tantalum, chromium, molybdenum, tungsten, an alloy of the above, and a combination of the foregoing.

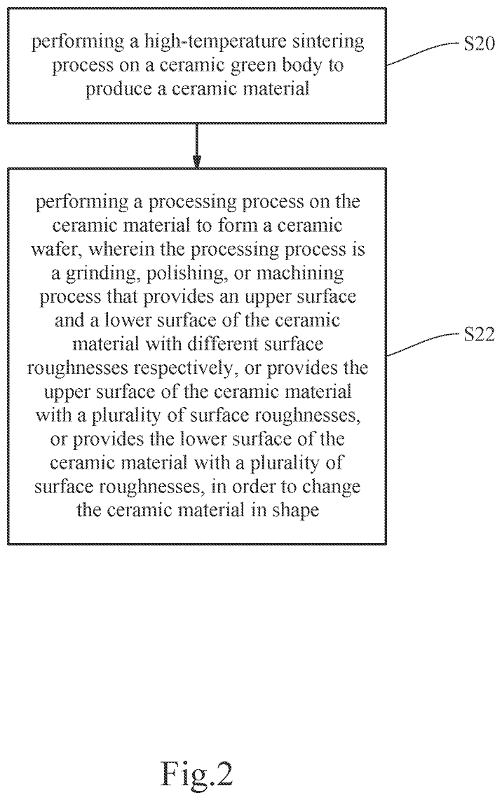

FIG. 2 shows a flowchart of the ceramic wafer manufacturing method according to an embodiment of the present invention. Referring to FIG. 2, step S20 is performing a high-temperature sintering process on a ceramic green body to produce a ceramic material, and step S22 is performing a processing process on the ceramic material to form a ceramic wafer, wherein the processing process is a grinding, polishing, or machining process that provides an upper surface and a lower surface of the ceramic material with different surface roughnesses respectively, or provides the upper surface of the ceramic material with a plurality of surface roughnesses, or provides the lower surface of the ceramic material with a plurality of surface roughnesses, in order to change the ceramic material in shape. According to a preferred embodiment of the invention, the processing process involves providing the ceramic wafer with at least one curved surface or preferably two curved surfaces, i.e., rendering the ceramic wafer into any of the shapes of the ceramic wafers 100a, 100b, and 100c in FIG. 1(A) to (C).

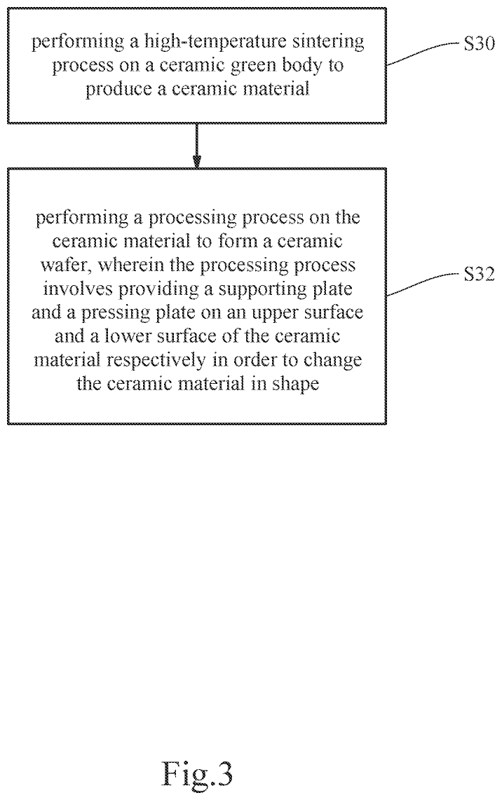

FIG. 3 shows a flowchart of the ceramic wafer manufacturing method according to another embodiment of the present invention. Referring to FIG. 3, step S30 is performing a high-temperature sintering process on a ceramic green body to produce a ceramic material, and step S32 is performing a processing process on the ceramic material to form a ceramic wafer, wherein the processing process involves providing a supporting plate and a pressing plate on an upper surface and a lower surface of the ceramic material respectively in order to change the ceramic material in shape. According to a preferred embodiment of the invention, the processing process involves providing the ceramic wafer with at least one curved surface or preferably two curved surfaces, i.e., rendering the ceramic wafer into any of the shapes of the ceramic wafers 100a, 100b, and 100c in FIG. 1 (A) to (C).

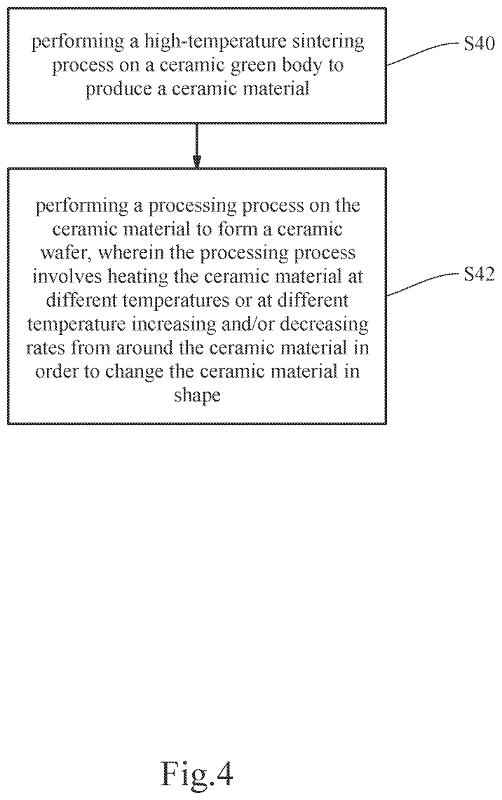

FIG. 4 shows a flowchart of the ceramic wafer manufacturing method according to still another embodiment of the present invention. Referring to FIG. 4, step S40 is performing a high-temperature sintering process on a ceramic green body to produce a ceramic material, and step S42 is performing a processing process on the ceramic material to form a ceramic wafer, wherein the processing process involves heating the ceramic material at different temperatures or at different temperature increasing and/or decreasing rates from around the ceramic material in order to change the ceramic material in shape. According to a preferred embodiment of the invention, the processing process involves providing the ceramic wafer with at least one curved surface or preferably two curved surfaces, i.e., rendering the ceramic wafer into any of the shapes of the ceramic wafers 100a, 100b, and 100c in FIG. 1(A) to (C).

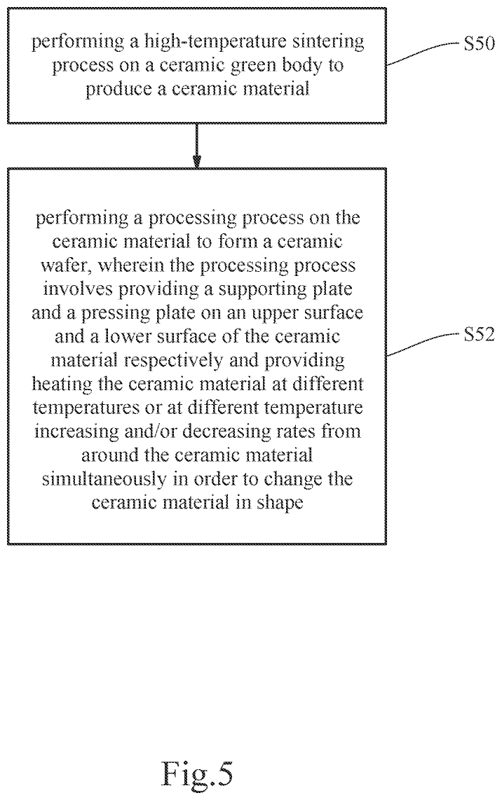

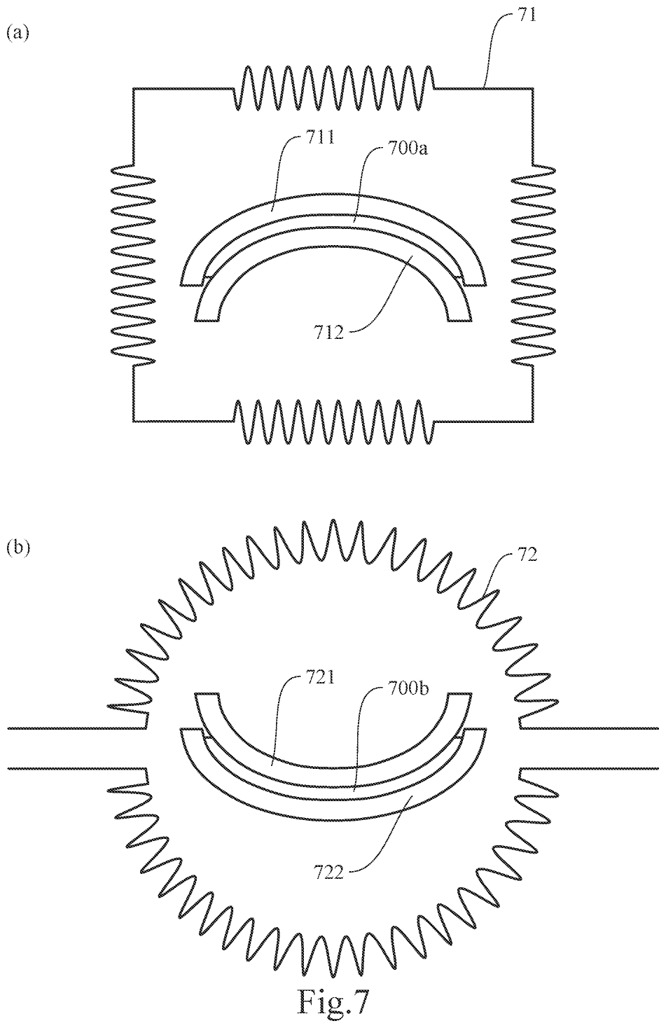

FIG. 5 shows a flowchart of the ceramic wafer manufacturing method according to yet another embodiment of the present invention, and FIG. 7 shows the ceramic wafer manufacturing method schematically. Referring to FIG. 5 and FIGS. 7(a) and (b), step S50 is performing a high-temperature sintering process on a ceramic green body to produce a ceramic material, and step S52 is performing a processing process on the ceramic material to form a ceramic wafer 700a/700b, wherein the processing process involves providing a pressing plate 711/721 and a supporting plate 712/722 on an upper surface and a lower surface of the ceramic material respectively and heating the ceramic material at different temperatures or at different temperature increasing and/or decreasing rates from around the ceramic material by a heater 71/72 in order to change the ceramic material in shape. According to a preferred embodiment of the invention, the processing process involves providing the ceramic wafer with at least one curved surface or preferably two curved surfaces, i.e., rendering the ceramic wafer into any of the shapes of the ceramic wafers 100a, 100b, and 100c in FIG. 1(A) to (C).

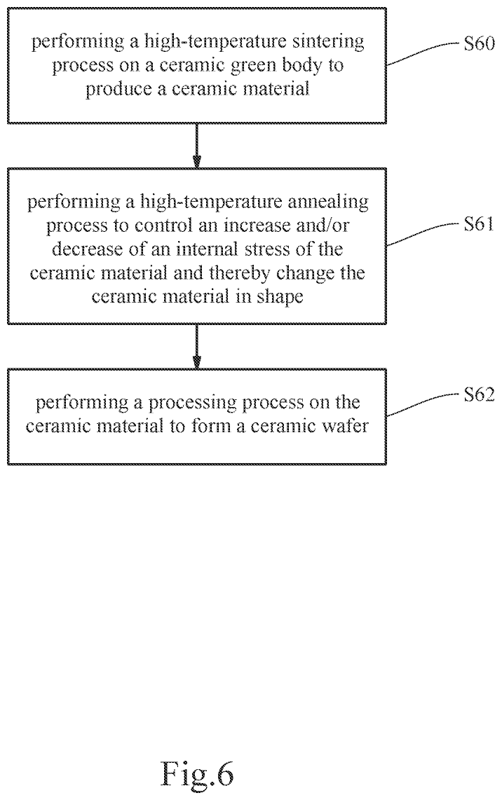

FIG. 6 shows a flowchart of the ceramic wafer manufacturing method according to still another embodiment of the present invention. Referring to FIG. 6, step S60 is performing a high-temperature sintering process on a ceramic green body, and step S61 is a high-temperature annealing process to be performed after the high-temperature sintering process. The ceramic green body forms a ceramic material after going through the high-temperature sintering process in step S60 and the high-temperature annealing process in step S61. The high-temperature annealing process is used to control the increase and/or decrease of the internal stress of the ceramic material and thereby change the ceramic material in shape. The step S62 that follows is performing a processing process on the ceramic material to form a ceramic wafer.

According to a preferred embodiment of the present invention, the ceramic green body is formed by stacking, and applying a high pressure to, a plurality of relatively thin green bodies.

According to some embodiments of the present invention, the processing process to be used may include an arbitrary combination of the aforesaid processing processes as appropriate.

It can be known from the above that the ceramic wafer and the manufacturing method thereof provided by the present invention are advantageous in that, by forming a warped or bowed ceramic wafer, it is made possible for the surface tension or surface internal stress caused by forming a thick IC film on the ceramic wafer to pull the ceramic wafer into a relatively flat configuration suitable for subsequent manufacturing processes that require wafer flatness.

While the present invention has been described above in detail, the foregoing embodiments are only some preferred ones of the invention and are not intended to be restrictive of the scope of the invention. Any equivalent change or modification that is made according to the appended claims shall fall within the scope of the invention.

1. A ceramic wafer, comprising an upper surface and a lower surface, wherein the ceramic wafer comprises at least one curved surface.

2. The ceramic wafer of claim 1, wherein the ceramic wafer includes an oxide ceramic, a nitride ceramic, or a carbide ceramic.

3. The ceramic wafer of claim 1, wherein the ceramic wafer comprises two said curved surfaces.

4. The ceramic wafer of claim 1, wherein the ceramic wafer comprises a bow ranging from +/−0.1 μm to 1000 μm.

5. The ceramic wafer of claim 1, wherein the ceramic wafer comprises a warp greater than or equal to 0.1 μm.

6. A manufacturing method of the ceramic wafer of claim 1, comprising the steps of:
performing a high-temperature sintering process on a ceramic green body to produce a ceramic material; and
performing a processing process on the ceramic material to form the ceramic wafer;
wherein the processing process is used to change the ceramic material in shape so as to form the ceramic wafer.

7. The manufacturing method of claim 6, wherein the processing process is a grinding, polishing, or machining process for imparting different surface roughnesses to an upper surface and a lower surface of the ceramic material respectively, or for imparting a plurality of surface roughnesses to the upper surface of the ceramic material, or for imparting a plurality of surface roughnesses to the lower surface of the ceramic material, in order to change the ceramic material in shape.

8. The manufacturing method of claim 6, wherein the processing process comprises providing a pressing plate and a supporting plate on an upper surface and a lower surface of the ceramic material respectively in order to change the ceramic material in shape.

9. The manufacturing method of claim 6, wherein the processing process comprises heating the ceramic material at different temperatures or at different temperature increasing and/or decreasing rates from around the ceramic material in order to change the ceramic material in shape.

10. The manufacturing method of claim 6, further comprising the step, to be performed after the high-temperature sintering process, of performing a high-temperature annealing process to control an increase and/or decrease of an internal stress of the ceramic material and thereby change the ceramic material in shape.
